(19) United States
(12) Patent Application Publication
(10) Pub. No.: US 2026/0032827 A1
(43) Pub. Date: Jan. 29, 2026

(54) CIRCUIT BOARD AND METHOD FOR PRODUCING CIRCUIT BOARD

(71) Applicant: Murata Manufacturing Co., Ltd., Nagaokakyo-shi (JP)

(72) Inventor: Tomohiro FURUMURA, Nagaokakyo-shi (JP)

(21) Appl. No.: 19/343,260

(22) Filed: Sep. 29, 2025

Related U.S. Application Data
(63) Continuation of application No. PCT/JP2024/014333, filed on Apr. 9, 2024.

(30) Foreign Application Priority Data
Apr. 20, 2023 (JP) 2023-069294

(51) Int. Cl. H05K 3/28; H05K 1/02; H05K 3/40

(52) U.S. Cl. CPC H05K 3/28; H05K 1/0298; H05K 3/4038

(57) ABSTRACT

A circuit board includes an insulating layer including first and second main surfaces facing each other in a thickness direction, first and second conductor layers respectively on the first and second main surfaces, an interlayer connection conductor penetrating the insulating layer in the thickness direction and connected to the first and second conductor layers, and a rustproof layer on a surface of the first or second conductor layers. The interlayer connection conductor includes a first portion made of a single metal and a second portion including at least a metal different from the first portion in the thickness direction. The first portion is bonded to the second portion with a first intermediate layer interposed therebetween and includes the metals included in the first and second portions. The second portion is bonded to the second conductor layer with a second intermediate layer interposed therebetween.

### CROSS REFERENCE TO RELATED APPLICATIONS

This application claims the benefit of priority to Japanese Patent Application No. 2023-069294 filed on Apr. 20, 2023 and is a Continuation Application of PCT Application No. PCT/JP2024/014333 filed on Apr. 9, 2024. The entire contents of each application are hereby incorporated herein by reference.

### BACKGROUND OF THE INVENTION

### 1. Field of the Invention

The present invention relates to circuit boards and methods for producing circuit boards.

### 2. Description of the Related Art

WO 2022/202322 A discloses a line board including an insulating layer and a conductor layer formed on one main surface of the insulating layer, in which the insulating layer has a hole with the conductor layer as a bottom and opened toward the other main surface of the insulating layer, a first via portion connected to the conductor layer and a second via portion connected to the first via portion are provided in the hole, the first via portion includes a conductive member and does not include a resin member, the first via portion has a protruding portion in which an end surface of the first via portion on a side of the second via portion protrudes toward the second via portion, a portion of the second via portion extends to between the protruding portion of the first via portion and the insulating layer, and is not in contact with the conductor layer connected to the first via portion.

WO 2022/202322 A describes that an interlayer connection conductor including a first via portion and a second via portion is formed by forming a first via portion partway through a hole by plating a hole provided in an insulating layer with conductor foil, and then forming a second via portion by filling a remaining portion of the hole in which the first via portion is formed with a conductive paste.

Further, WO 2022/202322 A describes that insulating layers including an insulating layer with conductor foil in which a first via portion and a second via portion are formed are sequentially stacked, and then the obtained stack is heat-pressed (collectively pressed) in a stacking direction to prepare a stacked substrate (hereinafter, also referred to as a multilayer circuit board).

In general, a surface of a conductor foil such as a Cu foil is subjected to rustproof treatment. By forming the rustproof layer on the surface of the conductor foil, oxidation of the conductor foil can be prevented, and inhibition of adhesion to the insulating layer can be reduced or prevented. On the other hand, the reaction between the conductive paste and the conductor foil is reduced or prevented by the rustproof layer, so that connection reliability between the interlayer connection conductor including the first via portion and the second via portion and the conductor layer may be deteriorated.

### SUMMARY OF INVENTION

Example embodiments of the present invention provide circuit boards each with excellent connection reliability between an interlayer connection conductor and a conductor layer, and methods for producing such circuit boards.

A circuit board according to an example embodiment of the present invention includes an insulating layer including a first main surface and a second main surface facing each other in a thickness direction, a first conductor layer on the first main surface of the insulating layer, a second conductor layer on the second main surface of the insulating layer, an interlayer connection conductor penetrating the insulating layer in the thickness direction and connected to the first conductor layer and the second conductor layer, and a rustproof layer on a surface of the first conductor layer or the second conductor layer. The interlayer connection conductor includes a first portion including a single metal and a second portion including at least a metal different from the first portion in the thickness direction. The first portion is bonded to the second portion with a first intermediate layer interposed therebetween, the first intermediate layer including the metal included in the first portion and the metal included in the second portion, and bonded to the first conductor layer without the first intermediate layer interposed therebetween. The second portion is bonded to the second conductor layer with a second intermediate layer interposed therebetween, the second intermediate layer including the metal included in the second portion and a metal included in the second conductor layer. The rustproof layer is provided at least at the interface between the first conductor layer and the insulating layer, and is not provided between the second portion and the second conductor layer.

A method for producing a circuit board according to an example embodiment of the present invention includes preparing a base in which a conductor layer is formed on one surface of an insulating layer and a rustproof layer is provided on at least a surface of the conductor layer on the insulating layer side, forming a via hole penetrating the insulating layer and exposing a portion of an upper surface of the conductor layer in the base, removing the rustproof layer in an exposed portion of the conductor layer, filling the via hole from which the rustproof layer has been removed with a first material made of a single metal, and then with a second material including at least a metal different from the first material, and stacking a plurality of bases including the base filled with the first material and the second material, and collectively pressing the stacked bases by applying heat and pressure.

According to example embodiments of the present invention, it is possible to provide circuit boards each with excellent connection reliability between an interlayer connection conductor and a conductor layer, and methods for producing such circuit boards.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view schematically illustrating an example of a circuit board according to an example embodiment of the present invention.

FIG. 2 is a cross-sectional view of the circuit board illustrated in FIG. 1 taken along line II-II.

FIG. 3 is a cross-sectional view schematically illustrating an example of a circuit board according to a first example embodiment of the present invention.

FIGS. 4A to 4G are cross-sectional views schematically illustrating an example of a method for producing a circuit board 1A according to an example embodiment of the present invention.

FIG. 5 is a cross-sectional view schematically illustrating an example of a circuit board according to a second example embodiment of the present invention.

FIG. 6 is a cross-sectional view schematically illustrating an example of a circuit board according to a third example embodiment of the present invention.

FIG. 7 is a cross-sectional view schematically illustrating an example of a circuit board according to a fourth example embodiment of the present invention.

FIG. 8 is a cross-sectional view schematically illustrating an example of a circuit board according to a fifth example embodiment of the present invention.

FIG. 9 is a cross-sectional view schematically illustrating another example of the circuit board according to the fifth example embodiment of the present invention.

FIG. 10 is a cross-sectional view schematically illustrating an example of a circuit board according to a sixth example embodiment of the present invention.

FIG. 11 is a cross-sectional view schematically illustrating another example of the circuit board according to the sixth example embodiment of the present invention.

FIG. 12 is a cross-sectional view schematically illustrating an example of a circuit board according to a seventh example embodiment of the present invention.

FIG. 13 is a cross-sectional view schematically illustrating an example of a circuit board according to an eighth example embodiment of the present invention.

FIG. 14A is a cross-sectional view schematically illustrating another example of the circuit board according to the eighth example embodiment of the present invention.

FIG. 14B is an example of an SEM photograph showing a cross section of the circuit board according to the eighth example embodiment of the present invention.

FIG. 15 is a cross-sectional view schematically illustrating an example of a circuit board according to a ninth example embodiment of the present invention.

FIG. 16 is a cross-sectional view schematically illustrating an example of a circuit board according to a tenth example embodiment of the present invention.

FIG. 17 is a cross-sectional view schematically illustrating another example of the circuit board according to the tenth example embodiment of the present invention.

FIGS. 18A to 18C are cross-sectional views schematically illustrating an example of a circuit board according to an eleventh example embodiment of the present invention.

FIG. 19 is a cross-sectional view schematically illustrating an example of a circuit board according to the eleventh example embodiment of the present invention.

FIG. 20 is a cross-sectional view schematically illustrating another example of the circuit board according to the eleventh example embodiment of the present invention.

FIG. 21 is a cross-sectional view schematically illustrating an example of a circuit board according to a twelfth example embodiment of the present invention.

FIG. 22 is a cross-sectional view schematically illustrating an example of a circuit board on which an electronic component is mounted.

FIG. 23 is a cross-sectional view schematically illustrating an example of a circuit board having a bent portion.

### DETAILED DESCRIPTION OF THE EXAMPLE EMBODIMENTS

Example embodiments of the present invention will be described in detail below with reference to the drawings.

Hereinafter, circuit boards and methods for producing circuit boards according to example embodiments of the present invention will be described.

However, the present invention is not limited to the following configurations, and changes can be appropriately applied thereto within a range not changing the scope of the present invention. The present invention also includes a combination of two or more of the individual preferred configurations of the present invention described below.

In the present specification, the term (for example, “vertical”, “parallel”, “orthogonal”, and the like) indicating the relationship between elements and the term indicating the shape of an element are not expressions indicating only a strict meaning, but are expressions meaning to include a substantially equivalent range, for example, a difference of about several %. In addition, in the present specification, “equivalent” is not an expression meaning only a case of being completely equivalent, but is an expression meaning that a case of being substantially equivalent includes, for example, a difference of about several %.

The drawings illustrated below are schematic views, and dimensions, scales of aspect ratios, and the like may be different from those of actual products. In the drawings, the same or corresponding portions are denoted by the same reference numerals. In each drawing, the same elements are denoted by the same reference numerals, and redundant description will be omitted.

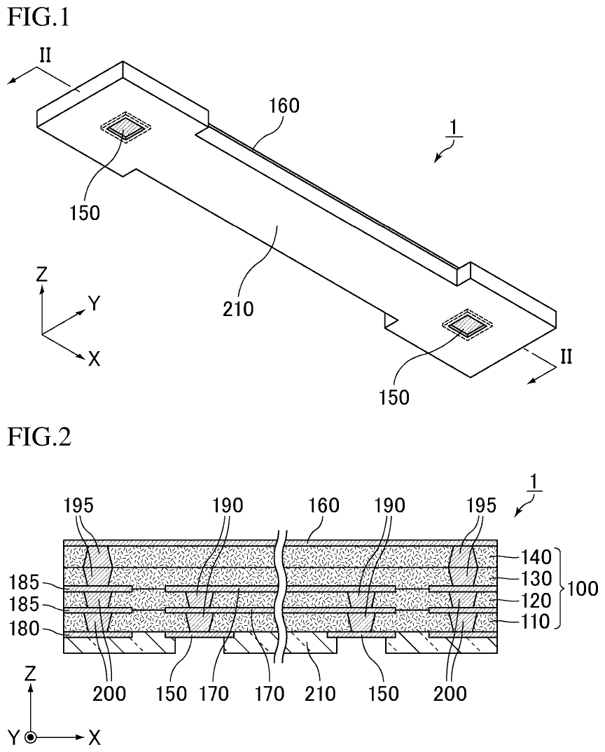

FIG. 1 is a perspective view schematically illustrating an example of a circuit board according to an example embodiment of the present invention. FIG. 2 is a cross-sectional view of the circuit board illustrated in FIG. 1 taken along line II-II.

A circuit board 1 illustrated in FIG. 1 includes an insulating base 100 formed by stacking insulating layers (first insulating layer 110, second insulating layer 120, third insulating layer 130, and fourth insulating layer 140), a conductor layer (mounting electrode 150, ground line 160, signal line 170, line 180, line 185) provided on or inside the insulating base 100, an interlayer connection conductor 190, an interlayer connection conductor 195, an interlayer connection conductor 200, and a protective layer 210, for example.

In the example illustrated in FIG. 1, the circuit board 1 is a multilayer circuit board including a plurality of insulating layers.

The circuit board 1 may be a rigid board or a flexible board. The circuit board 1 may include a bent portion.

On one main surface (lower surface in FIG. 2) of the insulating base 100, the mounting electrode 150, the line 180, and the protective layer 210 are provided. On the other main surface (upper surface in FIG. 2) of the insulating base 100, the ground line 160 is provided. The signal line 170 and the line 185 are provided between the first insulating layer 110 and the second insulating layer 120 and between the second insulating layer 120 and the third insulating layer 130.

The interlayer connection conductors 190 and 200 are provided inside the first insulating layer 110 and the second insulating layer 120. Among them, the interlayer connection conductors 190 connected to the signal line 170 overlap in the stacking direction (Z direction in FIG. 2). Therefore, the signal lines 170 are connected by the interlayer connection conductor 190 provided inside the first insulating layer 110 and the interlayer connection conductor 190 provided inside the second insulating layer 120 to define a transmission line. Further, the signal line 170 is connected to the mounting electrode 150 by an interlayer connection conductor 190 provided inside the first insulating layer 110.

Interlayer connection conductors 195 are provided inside the third insulating layer 130 and the fourth insulating layer 140.

The ground line 160 is connected to the line 180 by the interlayer connection conductor 200 provided inside the first insulating layer 110, the interlayer connection conductor 200 provided inside the second insulating layer 120, the interlayer connection conductor 195 provided inside the third insulating layer 130, and the interlayer connection conductor 195 provided inside the fourth insulating layer 140.

The line 185 is provided between each of the interlayer connection conductor 200 provided inside the first insulating layer 110 and the interlayer connection conductor 200 provided inside the second insulating layer 120, and between the interlayer connection conductor 200 provided inside the second insulating layer 120 and the interlayer connection conductor 195 provided inside the third insulating layer 130.

Although no line is provided between the interlayer connection conductor 195 provided inside the third insulating layer 130 and the interlayer connection conductor 195 provided inside the fourth insulating layer 140, a line may be provided between them. In addition, a line may be provided between the interlayer connection conductors 200 and between the interlayer connection conductor 195 and the interlayer connection conductor 200, or no line may be provided between them.

The protective layer 210 is, for example, a coverlay or a resist layer. The protective layer 210 may be provided on both main surfaces of the insulating base 100, or may be provided on one of the main surfaces.

The circuit board 1 includes at least one interlayer connection conductor described in each example embodiment of the present invention described below. For example, an interlayer connection conductor described in each example embodiment described below is preferably included as the interlayer connection conductor 190 connected to the signal line 170.

Each example embodiment illustrated below is an example, and partial replacement or combination of configurations illustrated in different example embodiments is possible. In the second and subsequent example embodiments, descriptions of matters common to the first example embodiment will be omitted, and only differences will be described. In particular, the same operation and advantageous effects by the same configuration will not be sequentially described for each example embodiment.

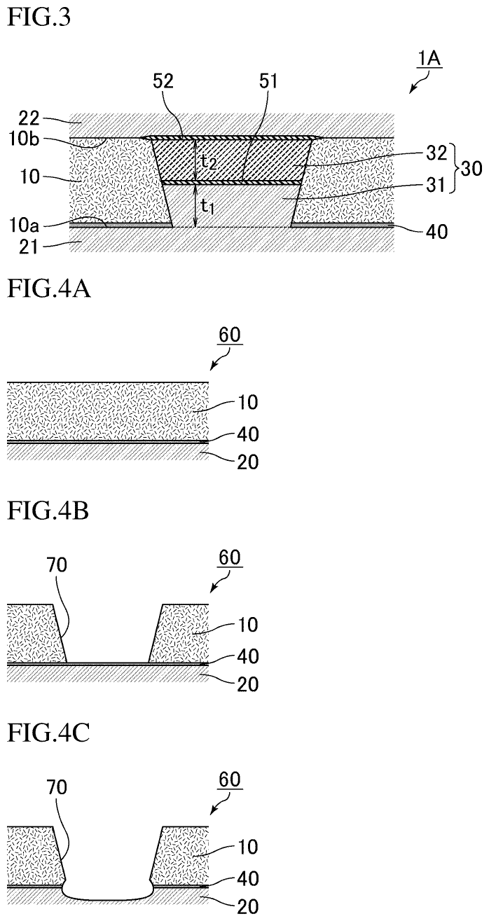

FIG. 3 is a cross-sectional view schematically illustrating an example of a circuit board according to a first example embodiment of the present invention.

Although an overall configuration is not illustrated in FIG. 3, a circuit board 1A includes an insulating layer 10 including a first main surface 10a and a second main surface 10b facing each other in a thickness direction (vertical direction in FIG. 3), a first conductor layer 21 provided on the first main surface 10a of the insulating layer 10, a second conductor layer 22 provided on the second main surface 10b of the insulating layer 10, an interlayer connection conductor 30 provided to penetrate the insulating layer 10 in the thickness direction and connected to the first conductor layer 21 and the second conductor layer 22, and a rustproof layer 40 provided on a surface of the first conductor layer 21 or the second conductor layer 22.

The insulating layer 10 is, for example, a resin insulating layer including a resin as a main component. In a case where the first conductor layer 21 or the second conductor layer 22 is a signal line, a resin having a low dielectric constant is included in the insulating layer 10, so that loss at the time of signal transmission can be reduced.

Alternatively, the insulating layer 10 may be a ceramic insulating layer including ceramic as a main component. When the first conductor layer 21 or the second conductor layer 22 is an antenna electrode, a ceramic having a high dielectric constant is included in the insulating layer 10, so that radiation or reception can be performed in a wide band.

The resin of the resin insulating layer may be, for example, a thermosetting resin or a thermoplastic resin, but is preferably a thermoplastic resin. In a case where the resin insulating layer is made of a thermoplastic resin, a plurality of resin sheets on which the conductor layer is provided can be stacked, and collectively press-bonded (collectively pressed) by heat treatment.

Examples of the thermosetting resin include an epoxy resin, a phenol resin, a polyimide resin or a modified resin thereof, or an acrylic resin.

Examples of the thermoplastic resin include a liquid crystal polymer (LCP), a fluororesin, a thermoplastic polyimide resin, a polyether ether ketone resin (PEEK), or a polyphenylene sulfide resin (PPS).

The resin insulating layer is, for example, preferably made of liquid crystal polymer (LCP). Liquid crystal polymers have lower water absorption than other thermoplastic resins. Therefore, when the resin insulating layer is made of a liquid crystal polymer, moisture remaining in the resin insulating layer can be reduced.

The resin insulating layer may include an inorganic material such as a ceramic filler, for example.

Examples of the ceramic filler include boron nitride, talc, or fused silica.

Examples of the ceramic of the ceramic insulating layer include a low-temperature co-fired ceramic (LTCC) or a high-temperature co-fired ceramic (HTCC).

The thickness of one layer of the insulating layer 10 is, for example, preferably about 10 μm or more and about 100 μm or less.

Each of the first conductor layer 21 and the second conductor layer 22 may have a patterned shape obtained by patterning the layer into lines, for example, or may have a planar shape spread over one surface. The shapes of the first conductor layer 21 and the second conductor layer 22 may be the same as or different from each other.

Each of the first conductor layer 21 and the second conductor layer 22 is, for example, a metal layer including at least one of copper, silver, aluminum, stainless steel, nickel, gold, or these metals. The materials of the first conductor layer 21 and the second conductor layer 22 may be the same as or different from each other. Both of the first conductor layer 21 and the second conductor layer 22 are, for example, preferably made of a metal foil, and more preferably made of a copper (Cu) foil.

Each of the first conductor layer 21 and the second conductor layer 22 may have a mat surface on one main surface and a shiny surface on the other main surface.

The thickness (length in the stacking direction) of each of the first conductor layer 21 and the second conductor layer 22 is, for example, preferably about 1 μm or more and about 35 μm or less, and more preferably about 6 μm or more and about 18 μm or less. The thickness of the first conductor layer 21 and the second conductor layer 22 may be the same as or different from each other.

The first conductor layer 21 and the second conductor layer 22 may or may not be parallel or substantially parallel to each other.

One insulating layer 10 may be provided between the first conductor layer 21 and the second conductor layer 22, or two or more insulating layers 10 may be provided. When two or more insulating layers 10 are provided between the first conductor layer 21 and the second conductor layer 22, the configurations of the insulating layers 10 may be the same as or different from each other. In addition, when two or more insulating layers 10 are provided between the first conductor layer 21 and the second conductor layer 22, the thickness of the insulating layers 10 may be the same as or different from each other.

The interlayer connection conductor 30 is provided so as to be connected to the first conductor layer 21 and the second conductor layer 22 while penetrating the insulating layer 10 in the thickness direction but not penetrating the first conductor layer 21 and the second conductor layer 22. Therefore, the interlayer connection conductor 30 penetrates the insulating layer(s) 10 in the thickness direction by the number of layers provided between the first conductor layer 21 and the second conductor layer 22.

In a cross section perpendicular or substantially perpendicular to the thickness direction, preferably the shape of the interlayer connection conductor 30 is circular. In this case, not only a perfect circle but also an ellipse, an oval, and the like are included in the circle.

The interlayer connection conductor 30 includes a first portion 31 and a second portion 32 in the thickness direction.

The first portion 31 includes a single metal.

The first portion 31 is, for example, a plated via. Here, the plating via means a film grown by a liquid phase method or a gas phase method, for example.

When the first portion 31 is a plated via, the metal included in the first portion 31 is preferably the same as the metal of the first conductor layer 21, and is, for example, Cu.

The second portion 32 includes at least a metal different from that of the first portion 31.

The second portion 32 is, for example, a paste via. Here, the paste via means a solidified paste. When the circuit board 1A is manufactured by collective pressing described later, the second portion 32 defines and functions as a bonding material, so that the first portion 31 and the second conductor layer 22 can be conductively connected.

When the second portion 32 is a paste via, examples of the metal included in the second portion 32 include Cu, Sn, Ag, Ni, Cr, Pt, Mo, Ga, Ge, Sb, In, Pb, or an alloy including at least one of these metals. The metal included in the second portion 32 may be the same as or different from the metal included in the first portion 31. The metal included in the second portion 32 is, for example, an alloy including Cu and Sn.

Alternatively, the second portion 32 may be a plated via.

When the second portion 32 is a plated via, examples of the metal included in the second portion 32 include Sn. By using Sn having a low melting point, it is easy to cause the second portion 32 to define and function as a bonding material.

The first portion 31 is bonded to the second portion 32 with a first intermediate layer 51 interposed therebetween, the first intermediate layer 51 including the metal included in the first portion 31 and the metal included in the second portion 32, and bonded to the first conductor layer 21 without the first intermediate layer 51 interposed therebetween.

As an example, in the second portion 32, the first intermediate layer 51 including Cu and Sn is provided at the end portion on the first portion 31 side. In this example, the first intermediate layer 51 is made of a Cu—Sn alloy such as Cu₃Sn or Cu₅Sn. However, the composition of the first intermediate layer 51 is different from the composition of the second portion 32.

The first portion 31 and the first conductor layer 21 are directly bonded without interposing a dissimilar material therebetween. Therefore, at the interface between the first portion 31 and the first conductor layer 21, there is a portion where different materials do not exist, that is, a portion where the first portion 31 and the first conductor layer 21 are in direct contact with each other.

The second portion 32 is bonded to the second conductor layer 22 with a second intermediate layer 52 interposed therebetween, the second intermediate layer 52 including the metal included in the second portion 32 and the metal included in the second conductor layer 22.

As an example, in the second portion 32, the second intermediate layer 52 including Cu and Sn is provided at the end portion on the second conductor layer 22 side. In this example, the second intermediate layer 52 is made of a Cu—Sn alloy such as Cu₃Sn or Cu₅Sn. However, the composition of the second intermediate layer 52 is different from the composition of the second portion 32.

In the example illustrated in FIG. 3, the second intermediate layer 52 extends to the interface between the second conductor layer 22 and the insulating layer 10, but as described later, the second intermediate layer 52 may not extend to the interface between the second conductor layer 22 and the insulating layer 10.

The first intermediate layer 51 may include one layer or two or more layers. Similarly, the second intermediate layer 52 may include one layer or two or more layers.

The first intermediate layer 51 and the second intermediate layer 52 can be confirmed, for example, by observing a cross section of the insulating layer 10 cut in a direction parallel or substantially parallel to the thickness direction using a scanning electron microscope (SEM). Since the first intermediate layer 51 and the second intermediate layer 52 are different in composition from both of the first portion 31 and the second portion 32, it is displayed in a color tone different from those of the first portion 31 and the second portion 32 in the SEM photograph.

Even when the types of included metal elements are the same, the case where the content ratios of the respective metal elements are different is also considered as being “different in composition”. For example, it can be said that the compositions of Cu₅Sn, Cu₃Sn, Cu₆Sn₅, or the like are all compositions including Cu and Sn as metal species, but the compositions are different from each other because the content ratios of the metal species are different.

The rustproof layer 40 is formed by, for example, subjecting the surface of the metal foil to a rustproof treatment using a metal such as Zn, Ni, Cr, Mo, or Pt.

The rustproof layer 40 is disposed at least at the interface between the first conductor layer 21 and the insulating layer 10, and is not disposed between the second portion 32 and the second conductor layer 22.

When the circuit board 1A is produced by collective pressing described later, for example, the rustproof layer 40 is disposed at the interface between the first conductor layer 21 and the insulating layer 10 to prevent oxidation of the metal foil such as the Cu foil of the first conductor layer 21, so that it is possible to reduce or prevent a decrease in adhesion between the first conductor layer 21 and the insulating layer 10.

When the circuit board 1A is manufactured by collective pressing, the thermal load applied to the interface between the first conductor layer 21 and the insulating layer 10 is greater than that applied to the interface between the second conductor layer 22 and the insulating layer 10. Therefore, preferably, the rustproof layer 40 is disposed at least at the interface between the first conductor layer 21 and the insulating layer 10.

On the other hand, when the rustproof layer 40 is disposed between the second portion 32 and the second conductor layer 22, a reaction between a material (for example, conductive paste) of the second portion 32 and a material (for example, metal foil) of the second conductor layer 22 is reduced or prevented by rustproof layer 40, and the second intermediate layer 52 is hardly formed. Therefore, by not disposing the rustproof layer 40 between the second portion 32 and the second conductor layer 22, the second intermediate layer 52 is easily formed, so that the connection reliability between the interlayer connection conductor 30 and the second conductor layer 22 can be improved.

In the circuit board 1A illustrated in FIG. 3, the rustproof layer 40 is not disposed at the interface between the second conductor layer 22 and the insulating layer 10. This makes it possible to prevent inhibition of a reaction between a material (for example, conductive paste) of the second portion 32 and a material (for example, metal foil) of the second conductor layer 22.

The rustproof layer 40 disposed at the interface between the first conductor layer 21 and the insulating layer 10 may be in contact with the first portion 31 or may not be in contact with the first portion 31.

As illustrated in FIG. 3, preferably, the rustproof layer 40 is not disposed between the first portion 31 and the first conductor layer 21. As described above, the first portion 31 is bonded to the first conductor layer 21 without the first intermediate layer 51 interposed therebetween. As a result, the connection strength between the interlayer connection conductor 30 and the first conductor layer 21 can be increased.

The shape of the interlayer connection conductor 30 is not limited to FIG. 3.

The second portion 32 may have a tapered shape in which the area of the end surface on the first conductor layer 21 side is smaller than the area of the end surface on the second conductor layer 22 side. Although the fragile second intermediate layer 52 may be provided at the end portion of the second portion 32 on the second conductor layer 22 side, the connection strength between the second portion 32 and the second conductor layer 22 can be increased by increasing the area of the second portion 32 at the portion connected to the second conductor layer 22.

Further, the first portion 31 may have a tapered shape in which the area of the end surface on the first conductor layer 21 side is smaller than the area of the end surface on the second conductor layer 22 side.

Therefore, as illustrated in FIG. 3, the interlayer connection conductor 30 may have a tapered shape in which the area of the end surface on the first conductor layer 21 side is smaller than the area of the end surface on the second conductor layer 22 side.

When the interlayer connection conductor 30 has a tapered shape, the height t₁ of the first portion 31 may be equal or substantially equal to the height t₂ of the second portion 32, may be less than the height t₂ of the second portion 32 (t₁<t₂), but is preferably greater than the height t₂ of the second portion 32 (t₁>t₂). When the interlayer connection conductor 30 has a tapered shape, the connection area between the first portion 31 and the second portion 32 is increased by making the height t₁ of the first portion 31 greater than the height t₂ of the second portion 32, so that the connection reliability of the interlayer connection conductor 30 can be improved.

In the example illustrated in FIG. 3, the end surface of the first portion 31 on the second conductor layer 22 side is flat. However, as described later, the end surface may protrude toward the second conductor layer 22 or may be recessed toward the first conductor layer 21.

The circuit board 1A is produced, for example, by the following method.

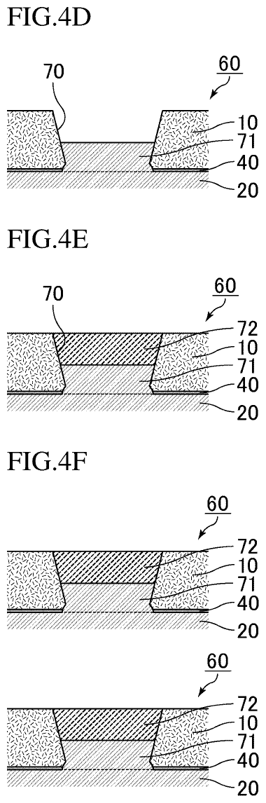

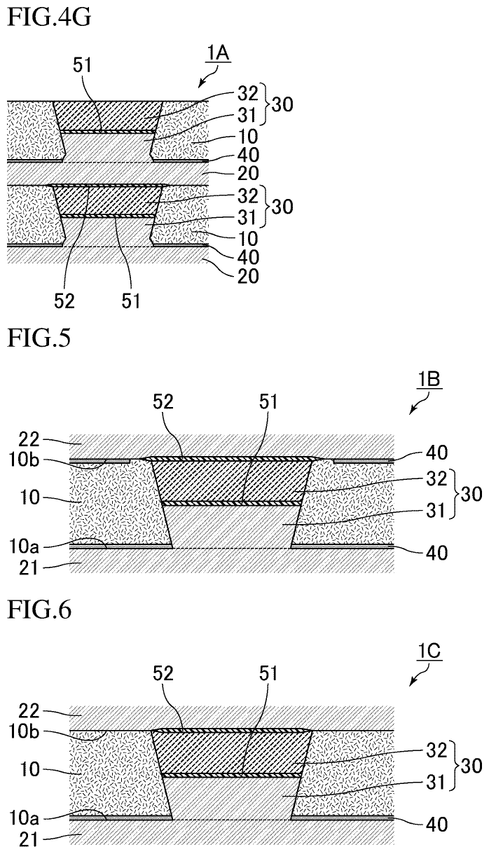

FIGS. 4A to 4G are cross-sectional views schematically illustrating an example of a method for producing a circuit board 1A. The circuit board 1A may be manufactured in a state of one chip (individual piece), or may be manufactured by manufacturing a collective board and then separating the collective board into individual pieces. The collective board here refers to a board including a plurality of circuit boards 1A.

First, as illustrated in FIG. 4A, a base 60 is prepared in which the conductor layer 20 is formed on one surface of the insulating layer 10, and the rustproof layer 40 is provided on at least a surface of the conductor layer 20 on the insulating layer 10 side.

For example, a metal foil such as a Cu foil is laminated on one main surface of the insulating layer 10, and the metal foil is patterned by photolithography to form the conductor layer 20. The insulating layer 10 is, for example, a resin sheet including a thermoplastic resin such as a liquid crystal polymer as a main component.

Next, as illustrated in FIG. 4B, a via hole 70 penetrating the insulating layer 10 and exposing a portion of the upper surface of the conductor layer 20 is formed in the base 60. The via hole 70 preferably has a tapered shape.

For example, the via hole 70 is formed in the insulating layer 10 with a laser, for example, such that the upper surface of the conductor layer 20 is exposed.

Subsequently, as illustrated in FIG. 4C, the rustproof layer 40 provided on the exposed portion of the conductor layer 20 is removed.

For example, the upper surface of the conductor layer 20 exposed from the via hole 70 is acid-cleaned, and then a soft etching, for example, is performed so that the rustproof layer 40 is removed.

Although not illustrated in FIGS. 4A to 4C, it is preferable to remove a rustproof layer (not illustrated) provided on a surface of the conductor layer 20 on a side opposite to the insulating layer 10. For example, the rustproof layers provided on the upper and lower surfaces of the conductor layer 20 may be simultaneously removed at the stage of FIG. 4C, or the rustproof layer provided on the lower surface of the conductor layer 20 may be removed at a stage before FIG. 4A.

Then, as illustrated in FIG. 4D, the via hole 70 from which the rustproof layer 40 has been removed is filled with a first material 71 including a single metal. The via hole 70 is partially filled with the first material 71. The height of the first material 71 is not limited as long as it does not exceed the thickness of the insulating layer 10.

For example, the via hole 70 from which the rustproof layer 40 has been removed is filled with a plating metal such as Cu as the first material 71 by a plating process such as an electrolytic plating process. The first portion 31 (see FIG. 4G) is formed of the first material 71.

Thereafter, as illustrated in FIG. 4E, the second material 72 including at least a metal different from the first material 71 is poured into the via hole 70, which has been filled with the first material 71. The space in the via hole 70 is filled with the first material 71 and the second material 72.

For example, the via hole 70 after being filled with the first material 71 is filled with a conductive paste including a metal material such as Cu or Sn and a resin material as the second material 72. The second material 72 is solidified by the heating press described later to form the second portion 32 (see FIG. 4G).

Although a plating metal such as Sn, for example, can be used as the second material 72, depending on the metal selected as the second material 72, there is a risk that the first material 71 defining and functioning as the underlying layer will remelt. Therefore, from the viewpoint of improving the degree of freedom of selection of the first material 71 and the second material 72, preferably, the via hole 70 from which the rustproof layer 40 has been removed is filled with the plating metal as the first material 71, and then with the conductive paste as the second material 72.

As illustrated in FIG. 4F, a plurality of bases including the base 60 filled with the first material 71 and the second material 72 are stacked. FIG. 4F illustrates an example in which the base 60 filled with the first material 71 and the second material 72 is continuously stacked, but is not limited as long as the base 60 filled with the first material 71 and the second material 72 is included.

Thereafter, as illustrated in FIG. 4G, heat and pressure are applied to press them at once. As a result, the circuit board 1A is produced.

According to this example of a producing method, the circuit board 1A can be easily manufactured by collectively pressing the insulating layers 10. Therefore, the manufacturing process of the circuit board 1A is reduced, and the manufacturing cost can be reduced.

FIG. 5 is a cross-sectional view schematically illustrating an example of a circuit board according to a second example embodiment of the present invention.

In the circuit board 1B illustrated in FIG. 5, the rustproof layer 40 is disposed at the interface between the second conductor layer 22 and the insulating layer 10 in a range not contacting the second intermediate layer 52. This makes it possible to prevent inhibition of a reaction between a material (for example, conductive paste) of the second portion 32 and a material (for example, metal foil) of the second conductor layer 22.

FIG. 6 is a cross-sectional view schematically illustrating an example of a circuit board according to a third example embodiment of the present invention.

In the circuit board 1C illustrated in FIG. 6, the second intermediate layer 52 does not extend to the interface between the second conductor layer 22 and the insulating layer 10. In FIG. 6, the rustproof layer 40 is not disposed at the interface between the second conductor layer 22 and the insulating layer 10, but may be disposed at the interface between the second conductor layer 22 and the insulating layer 10 in a range not contacting the second intermediate layer 52.

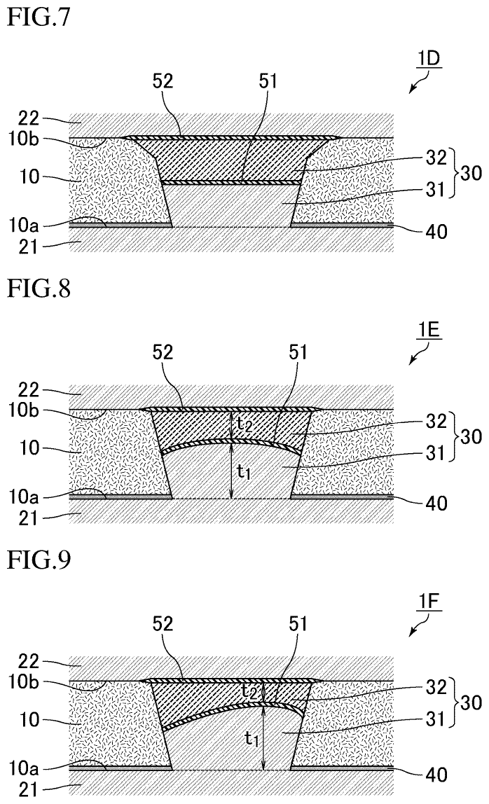

FIG. 7 is a cross-sectional view schematically illustrating an example of a circuit board according to a fourth example embodiment of the present invention.

In the circuit board 1D illustrated in FIG. 7, the second portion 32 has a tapered shape in which the area of the end surface on the first conductor layer 21 side is smaller than the area of the end surface on the second conductor layer 22 side, and the tapered shape has a stepwise varying inclination angle.

In the circuit board 1D illustrated in FIG. 7, the area of the second portion 32 of the portion connected to the second conductor layer 22 can be increased as compared with the circuit board 1A illustrated in FIG. 3. Therefore, the connection strength between the second portion 32 and the second conductor layer 22 can be further increased.

In the example illustrated in FIG. 7, the inclination angle of the tapered shape changes in two stages, but may change in three stages or may change in four or more stages.

Further, the first portion 31 may have a tapered shape in which the area of the end surface on the first conductor layer 21 side is smaller than the area of the end surface on the second conductor layer 22 side. In that case, the taper shape may have different inclination angles in stages.

FIG. 8 is a cross-sectional view schematically illustrating an example of a circuit board according to a fifth example embodiment of the present invention.

In the circuit board 1E illustrated in FIG. 8, the end surface of the first portion 31 on the second conductor layer 22 side protrudes toward the second conductor layer 22. In the example illustrated in FIG. 8, the end surface of the first portion 31 on the second conductor layer 22 side protrudes symmetrically.

FIG. 9 is a cross-sectional view schematically illustrating another example of the circuit board according to the fifth example embodiment of the present invention.

In the circuit board 1F illustrated in FIG. 9, similarly to FIG. 8, the end surface of the first portion 31 on the second conductor layer 22 side protrudes toward the second conductor layer 22. On the other hand, in the example illustrated in FIG. 9, the end surface of the first portion 31 on the second conductor layer 22 side protrudes asymmetrically.

As illustrated in FIG. 8 or FIG. 9, when the end surface of the first portion 31 on the second conductor layer 22 side protrudes toward the second conductor layer 22, the connection area between the first portion 31 and the second portion 32 increases, so that the connection strength between the first portion 31 and the second portion 32 can be increased.

The height t₁ of the first portion 31 may be equal or substantially equal to the height t₂ of the second portion 32, may be less than the height t₂ of the second portion 32 (t₁<t₂), but is preferably greater than the height t₂ of the second portion 32 (t₁>t₂). The height t₁ of the first portion 31 is defined as the height of the highest portion, and the height t₂ of the second portion 32 is defined as the height of the lowest portion.

In the examples illustrated in FIGS. 8 and 9, there is one peak, but there may be two or more peaks. When there are two or more peaks, their sizes, heights, and shapes, for example, may be the same or different.

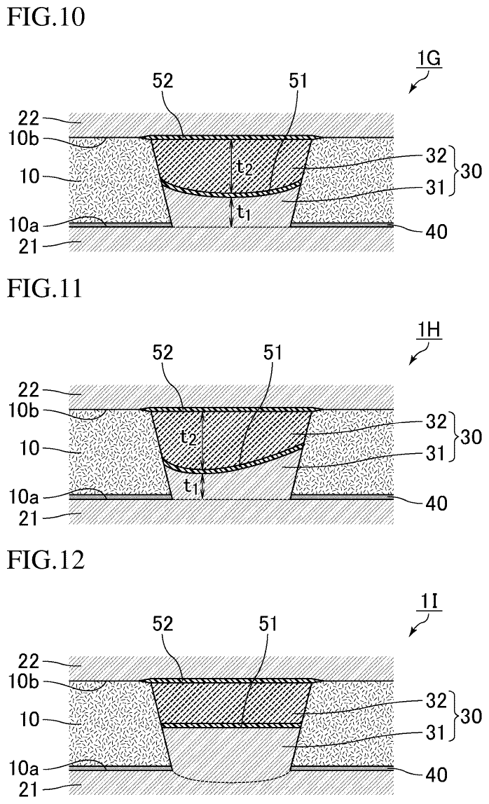

FIG. 10 is a cross-sectional view schematically illustrating an example of a circuit board according to a sixth example embodiment of the present invention.

In the circuit board 1G illustrated in FIG. 10, the end surface of the first portion 31 on the second conductor layer 22 side is recessed toward the first conductor layer 21. In the example illustrated in FIG. 10, the end surface of the first portion 31 on the second conductor layer 22 side is symmetrically recessed.

FIG. 11 is a cross-sectional view schematically illustrating another example of the circuit board according to the sixth example embodiment of the present invention.

In the circuit board 1H illustrated in FIG. 11, similarly to FIG. 10, the end surface of the first portion 31 on the second conductor layer 22 side is recessed toward the first conductor layer 21. On the other hand, in the example illustrated in FIG. 11, the end surface of the first portion 31 on the second conductor layer 22 side is asymmetrically recessed.

As illustrated in FIG. 10 or FIG. 11, when the end surface of the first portion 31 on the second conductor layer 22 side is recessed toward the first conductor layer 21, the connection area between the first portion 31 and the second portion 32 increases, so that the connection strength between the first portion 31 and the second portion 32 can be increased.

The height t₁ of the first portion 31 may be equal or substantially equal to the height t₂ of the second portion 32, may be less than the height t₂ of the second portion 32 (t₁<t₂), but is preferably greater than the height t₂ of the second portion 32 (t₁>t₂). The height t₁ of the first portion 31 is defined as the height of the lowest portion, and the height t₂ of the second portion 32 is defined as the height of the highest portion.

In the examples illustrated in FIGS. 10 and 11, there is one peak of the valley, but there may be two or more peaks of the valley. When there are two or more peaks of the valley, their sizes, depths, and shapes, for example, may be the same or different.

A portion protruding toward the second conductor layer 22 and a portion recessed toward the first conductor layer 21 may be mixed on the end surface of the first portion 31 on the second conductor layer 22 side.

FIG. 12 is a cross-sectional view schematically illustrating an example of a circuit board according to a seventh example embodiment of the present invention.

In the circuit board 1I illustrated in FIG. 12, the end surface of the first portion 31 on the first conductor layer 21 side protrudes to the first conductor layer 21 side from the interface between the first conductor layer 21 and the insulating layer 10.

As illustrated in FIG. 12, when the end surface of the first portion 31 on the first conductor layer 21 side protrudes to the first conductor layer 21 side from the interface between the first conductor layer 21 and the insulating layer 10, the connection area between the first portion 31 and the first conductor layer 21 increases, so that the connection strength between the first portion 31 and the first conductor layer 21 can be increased.

In the example illustrated in FIG. 12, the end surface of the first portion 31 on the first conductor layer 21 side protrudes symmetrically, but may protrude asymmetrically.

In the example illustrated in FIG. 12, there is one peak, but there may be two or more peaks. When there are two or more peaks, their sizes, heights, and shapes, for example, may be the same or different.

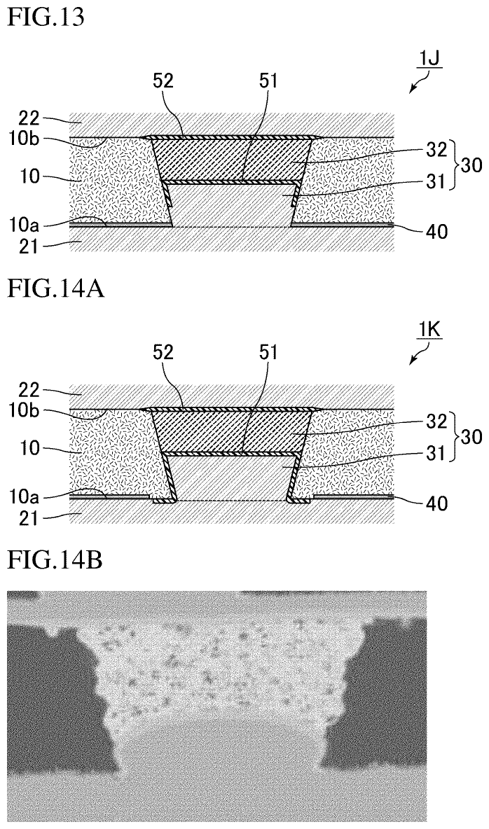

FIG. 13 is a cross-sectional view schematically illustrating an example of a circuit board according to an eighth example embodiment of the present invention.

As in the circuit board 1J illustrated in FIG. 13, the first intermediate layer 51 may extend to the interface between the first portion 31 and the insulating layer 10.

FIG. 14A is a cross-sectional view schematically illustrating another example of the circuit board according to the eighth example embodiment of the present invention. FIG. 14B is an example of an SEM photograph showing a cross section of the circuit board according to the eighth example embodiment of the present invention.

In the circuit board 1K illustrated in FIG. 14A, the first intermediate layer 51 extends to the interface between the first portion 31 and the insulating layer 10 and extends to the interface between the first conductor layer 21 and the insulating layer 10. Accordingly, the connection strength between the first portion 31 and the first conductor layer 21 can be further increased.

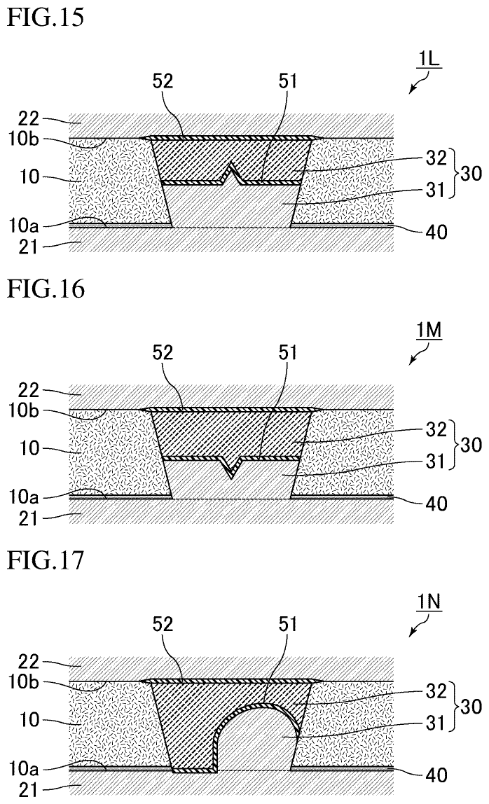

FIG. 15 is a cross-sectional view schematically illustrating an example of a circuit board according to a ninth example embodiment of the present invention.

In the circuit board 1L illustrated in FIG. 15, a portion protruding toward the second conductor layer 22 exists in a portion of the end surface of the first portion 31 on the second conductor layer 22 side.

As illustrated in FIG. 15, when there is a portion (hereinafter, also referred to as a protruding portion) protruding from a portion of the end surface of the first portion 31 on the second conductor layer 22 side, the connection area between the first portion 31 and the second portion 32 increases as in FIG. 8 or FIG. 9, so that the connection strength between the first portion 31 and the second portion 32 can be increased.

One protruding portion may exist or two or more protruding portions may exist in a portion of the end surface of the first portion 31 on the second conductor layer 22 side. When there are two or more protruding portions, their sizes, heights, and shapes, for example, may be the same or different.

The height of the protruding portion is, for example, about 1 μm or more and about 20 μm or less. The shape of the protruding portion is not limited to the shape illustrated in FIG. 15.

The maximum diameter of the protruding portion is, for example, about 1 μm or more and about 10 μm or less. Here, the maximum diameter of the protruding portion refers to a diameter when the cross-sectional shape is circular, and refers to a maximum length passing through the center of the cross-section when the cross-sectional shape is other than circular.

FIG. 16 is a cross-sectional view schematically illustrating an example of a circuit board according to a tenth example embodiment of the present invention.

In the circuit board 1M illustrated in FIG. 16, a portion recessed toward the first conductor layer 21 exists in a portion of the end surface of the first portion 31 on the second conductor layer 22 side.

As illustrated in FIG. 16, when there is a portion (hereinafter, also referred to as a recessed portion) recessed from a portion of the end surface of the first portion 31 on the second conductor layer 22 side, the connection area between the first portion 31 and the second portion 32 increases as in FIG. 10 or FIG. 11, so that the connection strength between the first portion 31 and the second portion 32 can be increased.

One recessed portion may exist or two or more recessed portions may exist in a portion of the end surface of the first portion 31 on the second conductor layer 22 side. When there are two or more recessed portions, their sizes, depths, and shapes, for example, may be the same or different.

The depth of the recessed portion is, for example, about 1 μm or more and about 20 μm or less. The shape of the recessed portion is not limited to the shape illustrated in FIG. 16.

The maximum diameter of the recessed portion is, for example, about 1 μm or more and about 10 μm or less. Here, the maximum diameter of the recessed portion refers to a diameter when the cross-sectional shape is circular, and refers to a maximum length passing through the center of the cross-section when the cross-sectional shape is other than circular.

A protruding portion and a recessed portion may be mixed on a portion of the end surface of the first portion 31 on the second conductor layer 22 side.

FIG. 17 is a cross-sectional view schematically illustrating another example of the circuit board according to the tenth example embodiment of the present invention.

As in a circuit board 1N illustrated in FIG. 17, a portion of the second portion 32 may be bonded to the first conductor layer 21. In that case, the first conductor layer 21 is bonded to the second portion 32 with the first intermediate layer 51 interposed therebetween.

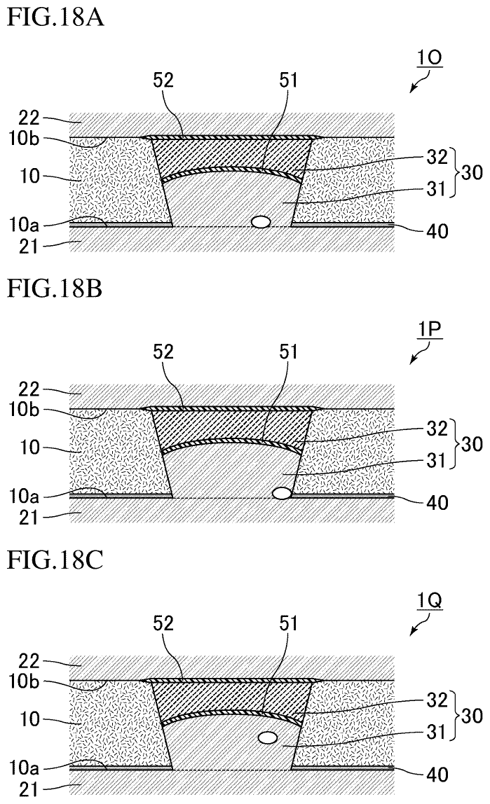

FIGS. 18A, 18B, and 18C are cross-sectional views schematically illustrating examples of a circuit board according to an eleventh example embodiment of the present invention.

As in the circuit board 1O illustrated in FIG. 18A, the circuit board 1P illustrated in FIG. 18B, or the circuit board 1Q illustrated in FIG. 18C, there may be a void inside the first portion 31. The number, size, and position, for example, of the voids are not limited. For example, the void may exist in the vicinity of the interface between the first portion 31 and the first conductor layer 21 as illustrated in FIG. 18A, may exist in the vicinity of the interface between the insulating layer 10 and the first conductor layer 21 as illustrated in FIG. 18B, or may exist in the vicinity of the first intermediate layer 51 as illustrated in FIG. 18C. In addition to the void or instead of the void, a residue of a resin (carbide) or an oxide of a copper foil (copper oxide) may be present, for example.

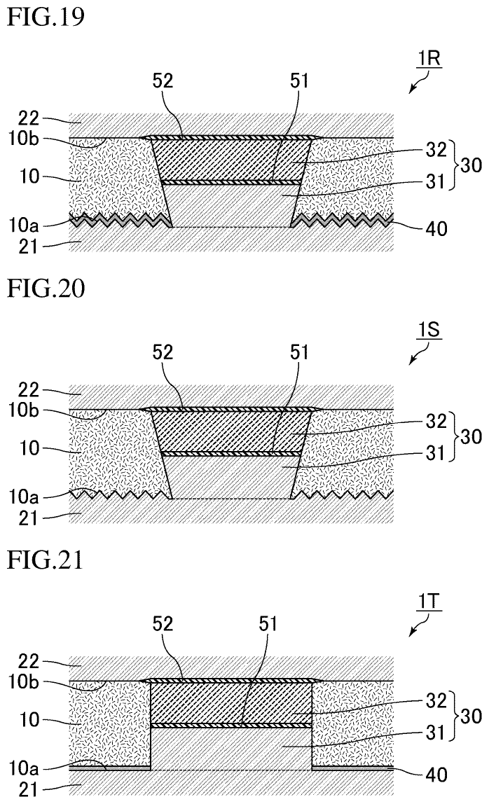

FIG. 19 is a cross-sectional view schematically illustrating an example of a circuit board according to an eleventh example embodiment of the present invention.

In the circuit board 1R illustrated in FIG. 19, the surface roughness of the portion of the first conductor layer 21 in contact with the insulating layer 10 is greater than the surface roughness of the portion of the second conductor layer 22 in contact with the insulating layer 10.

As illustrated in FIG. 19, by increasing the surface roughness of the first conductor layer 21 at the portion in contact with the insulating layer 10, the adhesion area between the insulating layer 10 and the first conductor layer 21 increases, so that the adhesion strength between the two can be increased. Therefore, for example, when an electronic component is mounted on the first conductor layer 21, the electronic component is hardly peeled off.

FIG. 20 is a cross-sectional view schematically illustrating another example of the circuit board according to the eleventh example embodiment of the present invention.

Also in the circuit board 1S illustrated in FIG. 20, the surface roughness of the portion of the first conductor layer 21 in contact with the insulating layer 10 is greater than the surface roughness of the portion of the second conductor layer 22 in contact with the insulating layer 10.

As with the circuit board 1S illustrated in FIG. 20, the rustproof layer 40 may not be disposed at the interface between the first conductor layer 21 and the insulating layer 10.

In the circuit board 1S illustrated in FIG. 20, the surface roughness of the portion of the first conductor layer 21 in contact with the insulating layer 10 is greater than the surface roughness of the portion of the second conductor layer 22 in contact with the insulating layer 10, so that the adhesion strength between the first conductor layer 21 and the insulating layer 10 can be increased even if the rustproof layer 40 is not disposed at the interface between the first conductor layer 21 and the insulating layer 10.

FIG. 21 is a cross-sectional view schematically illustrating an example of a circuit board according to a twelfth example embodiment of the present invention.

In the circuit board 1T illustrated in FIG. 21, the interlayer connection conductor 30 has a shape in which the area of the end surface on the first conductor layer 21 side is equal or substantially equal to the area of the end surface on the second conductor layer 22 side. That is, the interlayer connection conductor 30 does not have a tapered shape.

Specifically, the first portion 31 has a shape in which the area of the end surface on the first conductor layer 21 side is equal or substantially equal to the area of the end surface on the second conductor layer 22 side, and the second portion 32 has a shape in which the area of the end surface on the first conductor layer 21 side is equal or substantially equal to the area of the end surface on the second conductor layer 22 side.

When the interlayer connection conductor 30 has a tapered shape as in the circuit board 1A illustrated in FIG. 3, strain stress tends to concentrate on a necking portion (in particular, the necking portion between the interlayer connection conductor 30 and the first conductor layer 21) of the interlayer connection conductor 30. In contrast, when the interlayer connection conductor 30 does not have a tapered shape as in the circuit board 1T illustrated in FIG. 21, concentration of the strain stress on the necking portion of the interlayer connection conductor 30 is eliminated. Therefore, the stress applied to the interlayer connection conductor 30 is dispersed, so that the connection reliability is improved.

The circuit board of the present invention is not limited to the above example embodiments, and various applications and modifications can be made within the scope of the present invention with respect to the configuration and manufacturing conditions, for example, of the circuit board.

The circuit boards of example embodiments of the present invention are used, for example, as follows.

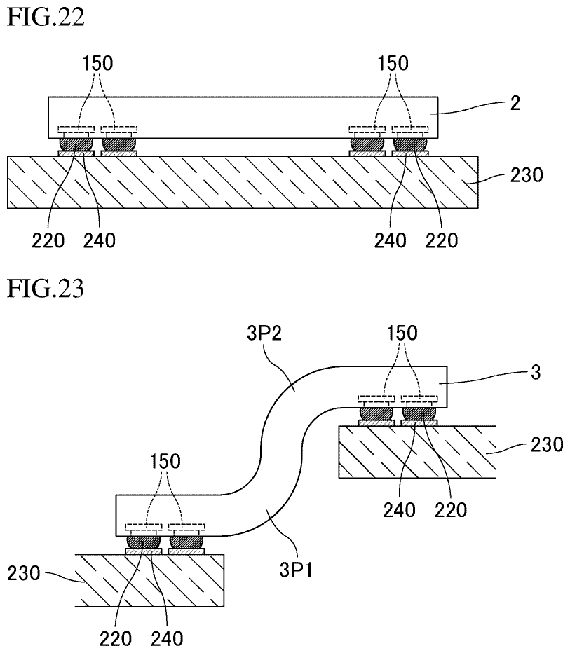

FIG. 22 is a cross-sectional view schematically illustrating an example of a circuit board on which an electronic component is mounted.

In the example illustrated in FIG. 22, the mounting electrode 150 of the circuit board 2 is connected to the external electrode 240 of the electronic component 230 via a conductive bonding material 220 such as solder, for example. Examples of the electronic component 230 include an integrated circuit (IC) and a connector.

FIG. 23 is a cross-sectional view schematically illustrating an example of a circuit board having a bent portion.

In the example illustrated in FIG. 23, the circuit board 3 includes bent portions 3P1 and 3P2. The number and shape, for example, of the bent portions are not limited.

The insulating layer of the circuit board 3 is, for example, preferably a resin insulating layer including a thermoplastic resin such as a liquid crystal polymer as a main component. In this case, the circuit board 3 can be manufactured by the above-described collective pressing.

Since the circuit board according to example embodiments of the present invention has the configuration described in the above example embodiments, even when the circuit board has a bent portion, rupture suppression against bending stress can be expected.

The following content is disclosed in the present specification.

<1>

A circuit board including an insulating layer including a first main surface and a second main surface facing each other in a thickness direction, a first conductor layer on the first main surface of the insulating layer, a second conductor layer on the second main surface of the insulating layer, an interlayer connection conductor penetrating the insulating layer in the thickness direction and connected to the first conductor layer and the second conductor layer, and a rustproof layer on a surface of the first conductor layer or the second conductor layer, wherein the interlayer connection conductor includes a first portion including a single metal and a second portion including at least a metal different from the first portion in the thickness direction, the first portion is bonded to the second portion with a first intermediate layer interposed therebetween, the first intermediate layer including the metal included in the first portion and the metal included in the second portion, and being bonded to the first conductor layer without the first intermediate layer interposed therebetween, the second portion is bonded to the second conductor layer with a second intermediate layer interposed therebetween, the second intermediate layer including the metal included in the second portion and a metal included in the second conductor layer, and the rustproof layer is provided at least at an interface between the first conductor layer and the insulating layer, and is not provided between the second portion and the second conductor layer.

<2>

The circuit board according to <1>, wherein the rustproof layer is not provided at an interface between the second conductor layer and the insulating layer.

<3>

The circuit board according to <1>, wherein the rustproof layer is provided at an interface between the second conductor layer and the insulating layer in a range not contacting the second intermediate layer.

<4>

The circuit board according to any one of <1> to <3>, wherein the second portion has a tapered shape in which an area of an end surface on the first conductor layer side is smaller than an area of an end surface on the second conductor layer side.

<5>

The circuit board according to <4>, wherein the tapered shape has a stepwise varying inclination angle.

<6>

The circuit board according to any one of <1> to <3>, wherein the interlayer connection conductor has a shape in which an area of an end surface on the first conductor layer side is equal or substantially equal to an area of an end surface on the second conductor layer side, the first portion has a shape in which the area of the end surface on the first conductor layer side is equal or substantially equal to the area of the end surface on the second conductor layer side, and the second portion has a shape in which the area of the end surface on the first conductor layer side is equal or substantially equal to the area of the end surface on the second conductor layer side.

<7>

The circuit board according to any one of <1> to <6>, wherein an end surface of the first portion on the second conductor layer side protrudes toward the second conductor layer or is recessed toward the first conductor layer.

<8>

The circuit board according to any one of <1> to <7>, wherein an end surface of the first portion on the first conductor layer side protrudes to the first conductor layer side from the interface between the first conductor layer and the insulating layer.

<9>

The circuit board according to any one of <1> to <8>, wherein the first intermediate layer extends to an interface between the first portion and the insulating layer.

<10>

The circuit board according to <9>, wherein the first intermediate layer extends to the interface between the first conductor layer and the insulating layer.

<11>

The circuit board according to any one of <1> to <10>, wherein a portion protruding toward the second conductor layer or a portion recessed toward the first conductor layer is provided in a portion of an end surface of the first portion on the second conductor layer side.

<12>

The circuit board according to any one of <1> to <11>, wherein a surface roughness of a portion of the first conductor layer in contact with the insulating layer is greater than a surface roughness of a portion of the second conductor layer in contact with the insulating layer.

<13>

The circuit board according to any one of <1> to <12>, wherein the second intermediate layer extends to an interface between the second conductor layer and the insulating layer.

<14>

The circuit board according to any one of <1> to <13>, wherein the rustproof layer is not provided between the first portion and the first conductor layer.

<15>

The circuit board according to any one of <1> to <14>, wherein the insulating layer includes a resin as a main component.

<16>

The circuit board according to any one of <1> to <14>, wherein the insulating layer includes ceramic as a main component.

<17>

The circuit board according to any one of <1> to <16>, wherein both of the first conductor layer and the second conductor layer includes a metal foil.

<18>

A method for producing a circuit board including preparing a base in which a conductor layer is formed on one surface of an insulating layer and a rustproof layer is provided on at least a surface of the conductor layer on the insulating layer side, forming a via hole penetrating the insulating layer and exposing a portion of an upper surface of the conductor layer in the base, removing the rustproof layer in an exposed portion of the conductor layer, filling the via hole from which the rustproof layer has been removed with a first material made of a single metal, and then with a second material including at least a metal different from the first material, and stacking a plurality of bases including the base filled with the first material and the second material, and collectively pressing the stacked bases by applying heat and pressure.

<19>

The method for producing a circuit board according to <18>, wherein the via hole from which the rustproof layer has been removed is filled with a plating metal as the first material, and is then filled with a conductive paste as the second material.

<20>

The method for producing a circuit board according to <18> or <19>, wherein the insulating layer includes a thermoplastic resin as a main component.

Furthermore, the following content is disclosed in the present specification.

<31>

A circuit board including an insulating layer including a first main surface and a second main surface facing each other in a thickness direction, a first conductor layer on the first main surface of the insulating layer, a second conductor layer on the second main surface of the insulating layer, and an interlayer connection conductor penetrating the insulating layer in the thickness direction and connected to the first conductor layer and the second conductor layer, wherein the interlayer connection conductor includes a first portion including a single metal and a second portion including at least a metal different from the first portion in the thickness direction, the first portion is bonded to the second portion with a first intermediate layer interposed therebetween, the first intermediate layer including the metal included in the first portion and the metal included in the second portion, and being bonded to the first conductor layer without the first intermediate layer interposed therebetween, the second portion is bonded to the second conductor layer with a second intermediate layer interposed therebetween, the second intermediate layer including the metal included in the second portion and a metal included in the second conductor layer, and a surface roughness of the first conductor layer in a portion in contact with the insulating layer is greater than a surface roughness of the second conductor layer in a portion in contact with the insulating layer.

<32>

The circuit board according to <31>, wherein the second portion has a tapered shape in which an area of an end surface on the first conductor layer side is smaller than an area of an end surface on the second conductor layer side.

<33>

The circuit board according to <32>, wherein the tapered shape has a stepwise varying inclination angle.

<34>

The circuit board according to <31>, wherein the interlayer connection conductor has a shape in which an area of an end surface on the first conductor layer side is equal or substantially equal to an area of an end surface on the second conductor layer side, the first portion has a shape in which the area of the end surface on the first conductor layer side is equal or substantially equal to the area of the end surface on the second conductor layer side, and the second portion has a shape in which the area of the end surface on the first conductor layer side is equal or substantially equal to the area of the end surface on the second conductor layer side.

<35>

The circuit board according to any one of <31> to <34>, wherein an end surface of the first portion on the second conductor layer side protrudes toward the second conductor layer or is recessed toward the first conductor layer.

<36>

The circuit board according to any one of <31> to <35>, wherein an end surface of the first portion on the first conductor layer side protrudes to the first conductor layer side from the interface between the first conductor layer and the insulating layer.

<37>

The circuit board according to any one of <31> to <36>, wherein the first intermediate layer extends to an interface between the first portion and the insulating layer.

<38>

The circuit board according to <37>, wherein the first intermediate layer extends to the interface between the first conductor layer and the insulating layer.

<39>

The circuit board according to any one of <31> to <38>, wherein a portion protruding toward the second conductor layer or a portion recessed toward the first conductor layer is provided in a portion of an end surface of the first portion on the second conductor layer side.

<40>

The circuit board according to any one of <31> to <39>, wherein the second intermediate layer extends to an interface between the second conductor layer and the insulating layer.

<41>

The circuit board according to any one of <31> to <40>, wherein the insulating layer includes a resin as a main component.

<42>

The circuit board according to any one of <31> to <40>, wherein the insulating layer includes ceramic as a main component.

<43>

The circuit board according to any one of <31> to <42>, wherein both of the first conductor layer and the second conductor layer include a metal foil.

<44>

The circuit board according to any one of <31> to <43>, further including a rustproof layer on the surface of the first conductor layer or the second conductor layer, wherein the rustproof layer is provided at least at the interface between the first conductor layer and the insulating layer, and is not provided between the second portion and the second conductor layer.

<45>

The circuit board according to <44>, wherein the rustproof layer is not provided at an interface between the second conductor layer and the insulating layer.

<46>

The circuit board according to <44>, wherein the rustproof layer is provided at an interface between the second conductor layer and the insulating layer in a range not contacting the second intermediate layer.

<47>

The circuit board according to any one of <44> to <46>, wherein the rustproof layer is not provided between the first portion and the first conductor layer.

<48>

A method for producing a circuit board including preparing a base in which a conductor layer is formed on one surface of an insulating layer, and the surface roughness of the conductor layer on the insulating layer side is greater than the surface roughness of a side opposite to the insulating layer, forming a via hole penetrating the insulating layer and exposing a portion of an upper surface of the conductor layer in the base, filling the via hole with a first material including a single metal, and then with a second material including at least a metal different from the first material, and stacking a plurality of bases including the base filled with the first material and the second material, and collectively pressing the stacked bases by applying heat and pressure.

<49>

The method for producing a circuit board according to <48>, wherein the via hole is filled with a plating metal as the first material, and is then filled with a conductive paste as the second material.

<50>

The method for producing a circuit board according to <48> or <49>, wherein the insulating layer includes a thermoplastic resin as a main component.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A circuit board comprising:
an insulating layer including a first main surface and a second main surface facing each other in a thickness direction;
a first conductor layer on the first main surface of the insulating layer;
a second conductor layer on the second main surface of the insulating layer;
an interlayer connection conductor penetrating the insulating layer in the thickness direction and connected to the first conductor layer and the second conductor layer; and
a rustproof layer on a surface of the first conductor layer or the second conductor layer; wherein
the interlayer connection conductor includes a first portion including a single metal and a second portion including at least a metal different from the first portion in the thickness direction;
the first portion is bonded to the second portion with a first intermediate layer interposed therebetween, the first intermediate layer including the metal included in the first portion and the metal included in the second portion, and being bonded to the first conductor layer without the first intermediate layer interposed therebetween;
the second portion is bonded to the second conductor layer with a second intermediate layer interposed therebetween, the second intermediate layer including the metal included in the second portion and a metal included in the second conductor layer; and
the rustproof layer is provided at least at an interface between the first conductor layer and the insulating layer, and is not provided between the second portion and the second conductor layer.

2. The circuit board according to claim 1, wherein the rustproof layer is not provided at an interface between the second conductor layer and the insulating layer.

3. The circuit board according to claim 1, wherein the rustproof layer is provided at an interface between the second conductor layer and the insulating layer in a range not contacting the second intermediate layer.

4. The circuit board according to claim 1, wherein the second portion has a tapered shape in which an area of an end surface on the first conductor layer side is smaller than an area of an end surface on the second conductor layer side.

5. The circuit board according to claim 4, wherein the tapered shape has a stepwise varying inclination angle.

6. The circuit board according to claim 1, wherein
the interlayer connection conductor has a shape in which an area of an end surface on the first conductor layer side is equal or substantially equal to an area of an end surface on the second conductor layer side;
the first portion has a shape in which the area of the end surface on the first conductor layer side is equal or substantially equal to the area of the end surface on the second conductor layer side; and
the second portion has a shape in which the area of the end surface on the first conductor layer side is equal or substantially equal to the area of the end surface on the second conductor layer side.

7. The circuit board according to claim 1, wherein an end surface of the first portion on the second conductor layer side protrudes toward the second conductor layer or is recessed toward the first conductor layer.

8. The circuit board according to claim 1, wherein an end surface of the first portion on the first conductor layer side protrudes to the first conductor layer side from the interface between the first conductor layer and the insulating layer.

9. The circuit board according to claim 1, wherein the first intermediate layer extends to an interface between the first portion and the insulating layer.

10. The circuit board according to claim 9, wherein the first intermediate layer extends to the interface between the first conductor layer and the insulating layer.

11. The circuit board according to claim 1, wherein a portion protruding toward the second conductor layer or a portion recessed toward the first conductor layer is provided in a portion of an end surface of the first portion on the second conductor layer side.

12. The circuit board according to claim 1, wherein a surface roughness of a portion of the first conductor layer in contact with the insulating layer is greater than a surface roughness of a portion of the second conductor layer in contact with the insulating layer.

13. The circuit board according to claim 1, wherein the second intermediate layer extends to an interface between the second conductor layer and the insulating layer.

14. The circuit board according to claim 1, wherein the rustproof layer is not provided between the first portion and the first conductor layer.

15. The circuit board according to claim 1, wherein the insulating layer includes a resin as a main component.

16. The circuit board according to claim 1, wherein the insulating layer includes ceramic as a main component.

17. The circuit board according to claim 1, wherein both the first conductor layer and the second conductor layer include a metal foil.

18. A method for producing a circuit board comprising:
preparing a base in which a conductor layer is formed on one surface of an insulating layer and a rustproof layer is provided on at least a surface of the conductor layer on the insulating layer side;
forming a via hole penetrating the insulating layer and exposing a portion of an upper surface of the conductor layer in the base;
removing the rustproof layer provided in an exposed portion of the conductor layer;
filling the via hole from which the rustproof layer has been removed with a first material made of a single metal, and then with a second material including at least a metal different from the first material; and
stacking a plurality of bases including the base filled with the first material and the second material, and collectively pressing the stacked bases by applying heat and pressure.

19. The method for producing a circuit board according to claim 18, wherein the via hole from which the rustproof layer has been removed is filled with a plating metal as the first material, and is then filled with a conductive paste as the second material.

20. The method for producing a circuit board according to claim 18, wherein the insulating layer includes a thermoplastic resin as a main component.
